(19) United States
(12) Patent Application Publication
(10) Pub. No.: US 2011/0044359 A1
(43) Pub. Date: Feb. 24, 2011

(54) Intracavity Conversion Utilizing Narrow Band Reflective SOA

(76) Inventors: Douglas Llewellyn Butler, Painted Post, NY (US); Martin Hai Hu, Painted Post, NY (US); Anping Liu, Big Flats, NY (US)

Correspondence Address: CORNING INCORPORATED, SP-TI-3-1, CORNING, NY, 14831, US

(21) Appl. No.: 12/543,123

(22) Filed: Aug. 18, 2009

(51) Int. Cl. H01S 3/10; H01S 5/187

(52) U.S. Cl. 372/20; 372/50.11; 372/22

(57) ABSTRACT

An external cavity laser source is provided comprising an external laser cavity, a tunable distributed Bragg reflector (DBR), a DBR tuning element, an output reflector, a semiconductor optical amplifier (SOA), a frequency-selective optical coupler/reflector, and a wavelength conversion device. The tunable DBR, the DBR tuning element, the SOA, and the output reflector are configured to generate a fundamental laser signal characterized by a fundamental bandwidth that is narrower than the QPM bandwidth of the wavelength conversion device and can be tuned to a fundamental center wavelength within the QPM bandwidth. The frequency-selective optical coupler/reflector is configured for substantially non-reflective two-way transmission of optical signals at the fundamental center wavelength and is further configured for substantially complete reflection of wavelength-converted optical signals generated by the wavelength conversion device. The output reflector is configured for substantially non-reflective transmission of wavelength-converted optical signals generated by the wavelength conversion device and for substantially complete reflection of optical signals at the fundamental center wavelength. Additional embodiments are disclosed and claimed.

### BACKGROUND

The present disclosure relates to frequency-converted laser sources and, more particularly, to a reduced-cost frequency converted laser source configured for improved wavelength conversion efficiency.

### BRIEF SUMMARY

Although the various concepts of the present disclosure are not limited to lasers that operate in any particular part of the optical spectrum, reference is frequently made herein to wavelength converted green lasers, where a second-order or higher order wavelength conversion device, e.g., a periodically poled lithium niobate (PPLN) SHG (second harmonic generation) crystal, is used to convert a fundamental laser signal to a shorter wavelength signal. According to the subject matter of the present disclosure, laser systems are provided to address continuously increasing cost and performance demands for frequency-converted laser sources.

In accordance with one embodiment of the present disclosure, an external cavity laser source is provided comprising an external laser cavity, a tunable distributed Bragg reflector (DBR), a DBR tuning element, an output reflector, a semiconductor optical amplifier (SOA), a frequency-selective optical coupler/reflector, and a wavelength conversion device. The tunable DBR, the DBR tuning element, the SOA, and the output reflector are configured to generate a fundamental laser signal characterized by a fundamental bandwidth that is narrower than the QPM bandwidth of the wavelength conversion device and can be tuned to a fundamental center wavelength within the QPM bandwidth. The frequency-selective optical coupler/reflector is configured for substantially non-reflective two-way transmission of optical signals at the fundamental center wavelength and is further configured for substantially complete reflection of wavelength-converted optical signals generated by the wavelength conversion device. Downstream optical signals at the fundamental center wavelength originating from a DBR side of the external laser cavity are transmitted along the optical path towards the wavelength conversion device and the output reflector. Upstream optical signals at the fundamental center wavelength originating from an output side of the external laser cavity are transmitted along the optical path towards the SOA and the tunable DBR. The output reflector is configured for substantially non-reflective transmission of wavelength-converted optical signals generated by the wavelength conversion device and for substantially complete reflection of optical signals at the fundamental center wavelength.

### BRIEF DESCRIPTION OF THE SEVERAL VIEWS OF THE DRAWINGS

The following detailed description of specific embodiments of the present disclosure can be best understood when read in conjunction with the following drawings, where like structure is indicated with like reference numerals and in which:

FIG. 1 illustrates an external cavity laser source according to one embodiment of the present disclosure;

FIGS. 2 and 3 illustrate external cavity laser sources according to two of the many contemplated alternative embodiments of the present disclosure; and

FIGS. 4-6 illustrate three different optical configurations for directing a fundamental optical signal through a wavelength conversion device in the context of the present disclosure.

### DETAILED DESCRIPTION

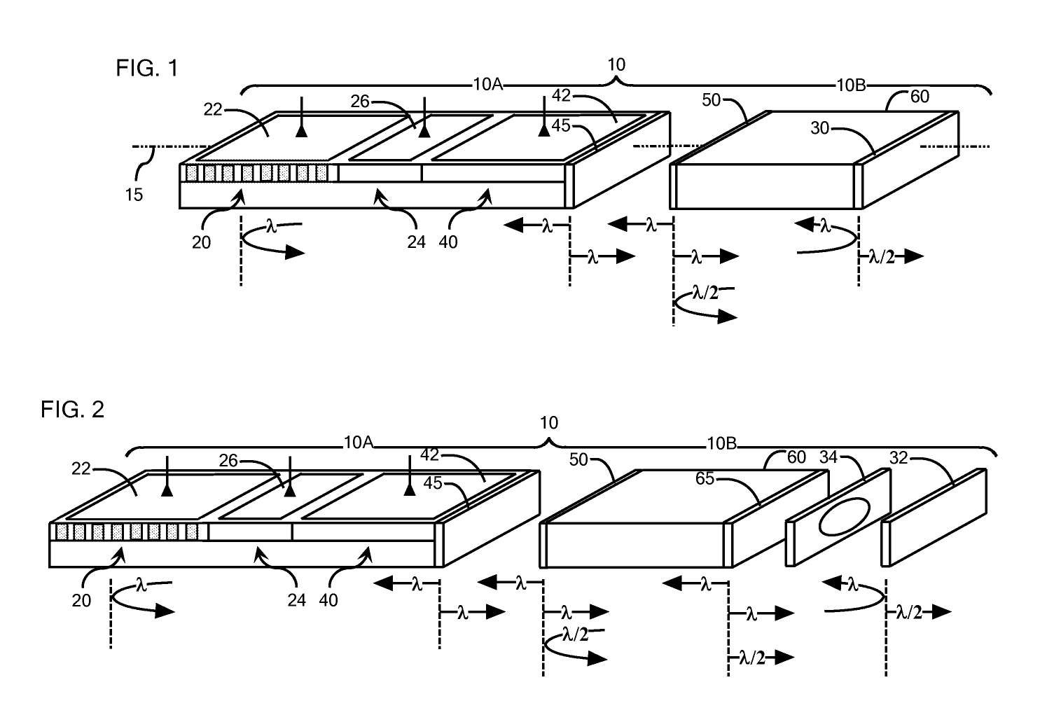

Referring initially to FIG. 1, an external cavity laser source is provided comprising an external laser cavity 10, a tunable distributed Bragg reflector (DBR) 20, a DBR tuning element 22, an output reflector 30, a semiconductor optical amplifier (SOA) 40, a frequency-selective optical coupler/reflector 50, and a wavelength conversion device 60.

The external laser cavity 10 is defined along an optical path 15 between the tunable DBR 20 and the output reflector 30. The SOA 40 is positioned in the external laser cavity 10 along the optical path 15 between the tunable DBR 20 and the frequency-selective optical coupler/reflector 50. The wavelength conversion device 60 is characterized by a QPM (quasi-phase matching) bandwidth and is positioned in the external laser cavity 10 along the optical path 15 between the frequency-selective optical coupler/reflector 50 and the output reflector 30.

The tunable DBR 20, the DBR tuning element 22, the SOA 40, and the output reflector 30 are configured to generate a fundamental laser signal λ characterized by a fundamental bandwidth that is narrower than the QPM bandwidth of the wavelength conversion device 60. Further, the fundamental laser signal λ can be tuned to a fundamental center wavelength within the QPM bandwidth.

For the purposes of describing and defining the present invention, it is noted that “substantially non-reflective transmission” of an optical signal should be taken to denote transmission within a fraction of one percent of total transmission. Similarly, “substantially complete reflection” of an optical signal should be taken to denote reflection within a fraction of one percent of total reflection. As is illustrated schematically in FIGS. 1-3, the frequency-selective optical coupler/reflector 50 is configured for substantially non-reflective two-way transmission of optical signals at the fundamental center wavelength λ and for substantially complete reflection of wavelength-converted optical signals λ/2 generated by the wavelength conversion device 60. Accordingly, the frequency-selective optical coupler/reflector 50 helps to ensure that downstream optical signals λ, i.e., propagating left-to-right in FIGS. 1-3, and which originate from a DBR side 10A of the external laser cavity 10, are transmitted along the optical path 15 towards the wavelength conversion device 60 and the output reflector 30. Further, upstream optical signals λ, i.e., propagating right-to-left in FIGS. 1-3, and which originate from an output side 10B of the external laser cavity 10 are transmitted along the optical path 15 towards the SOA 40 and the tunable DBR 20.

As is further illustrated schematically in FIGS. 1-3, the output reflector 30 is configured for substantially non-reflective transmission of the wavelength-converted optical signals λ/2 that are generated by the wavelength conversion device 60. The output reflector 30 is also configured for substantially complete reflection of optical signals at the fundamental center wavelength λ. In this manner, wavelength-converted optical signals λ/2 are permitted to pass as the output signal while optical signals at the fundamental center wavelength λ remain in the external laser cavity 10. The result is that the fundamental-wavelength light λ has a relatively high optical intensity inside the laser cavity 10 and passes through the wavelength conversion device 60 in both the downstream and upstream directions, achieving high overall wavelength conversion efficiency. The high optical intensity of the fundamental-wavelength light λ generally allows the use of shorter wavelength conversion devices like waveguide SHG crystals and bulk SHG crystals.

The frequency-selective optical coupler/reflector 50 may be presented in a variety of forms, as one or more optical components. For example, the frequency-selective optical coupler/reflector 50 may comprise a dichroic mirror formed as a directly-deposited coating on an output facet of the SOA 40, an input facet of the wavelength conversion device 60, or on both faces. In FIGS. 1 and 2, the frequency-selective optical coupler/reflector 50 is formed on the input facet of the wavelength conversion device 60 while an anti-reflective coating 45 is formed on the output facet of the SOA 40. Anti-reflective coatings may be provided on opposing faces of the SOA 40 and the wavelength conversion device 60 for substantially non-reflective transmission of the fundamental laser signal λ. Alternatively, or additionally, it is contemplated that the output facet of the SOA 40 and the input facet of the wavelength conversion device 60 may be configured to have nearly zero reflectivity at the fundamental wavelength λ by tilting the output facet of the SOA 40, relative to the optical path 15.

The SOA 40 may be provided as gain section that is configured to provide optical gain at the fundamental center wavelength λ under electrical current injection via the SOA control electrode 42 illustrated schematically in FIGS. 1-3. As an example, for efficient operation at a fundamental wavelength of 1060 nm, the gain section SOA 40 can comprise a suitably configured InGaAs quantum well structure having a configuration as taught in conventional or yet-to-be developed publications in the art. Preferably, the SOA 40 and the tunable DBR 20 are fabricated on a common substrate, as is illustrated in FIGS. 1-3.

The modulation speed of the SOA 40, which utilizes a semiconductor material and direct current injection to achieve optical gain for the fundamental optical signal λ, can be significantly faster than diode pumped solid-state lasers because the upper-level lifetime of the semiconductor material, e.g., an InGaAs/AlGaAs material system, is much shorter than that of a solid-state material, e.g., Nd-doped YAG. The modulation bandwidth of the designs proposed herein is likely determined by the photon lifetime of the fundamental signal λ, which can be engineered by designing the external laser cavity. It is estimated that achievable modulation bandwidths from a few tens of MHz to a few hundreds of MHz will be obtainable in practicing the embodiments disclosed herein. Further, it is contemplated that wavelength fluctuations caused by the spontaneous switching of the longitudinal modes in the intra-cavity resonators disclosed herein will have a response time on the order of nanoseconds. In addition, polarization control in the narrow-band reflective SOA disclosed herein is readily achievable because of the intrinsic selection of preferred polarization states in the system. The resulting shorter upper-level life time and superior stability of the fundamental-wavelength polarization state are particularly advantageous.

Referring to FIGS. 4-6, the laser source may further comprise one or more coupling lenses positioned along the optical path 15 between the SOA 40 and the wavelength conversion device 60. Although the SOA 40 and the wavelength conversion device 60 may be optically coupled via conventional or yet-to-be developed proximity coupling techniques, FIGS. 4-6 illustrate three different configurations for utilizing one or more coupling lenses to achieve optimum optical coupling where the wavelength conversion device 60 comprises a bulk crystal. In FIG. 4, the wavelength conversion device 60 comprises a bulk crystal and the coupling lens comprises a focusing lens 70 that is configured to define a beam waist at an output facet of the bulk crystal. In FIG. 5, the wavelength conversion device 60 comprises a bulk crystal and the coupling lens comprises a collimating lens 75 that is configured to collimate the fundamental laser signal λ as it propagates along the optical path 15 through the bulk crystal. Typically, the collimated cross sectional diameter of the fundamental laser signal λ will be between approximately 5 μm and approximately 50 μm. In FIG. 6, the wavelength conversion device 60 also comprises a bulk crystal, the coupling lens comprises a focusing lens 70, and the output reflector is configured as a concave reflector 35. The focusing lens 70 and the concave reflector 35 cooperate to define a beam waist in an intermediate location along the optical path 15 in the bulk crystal.

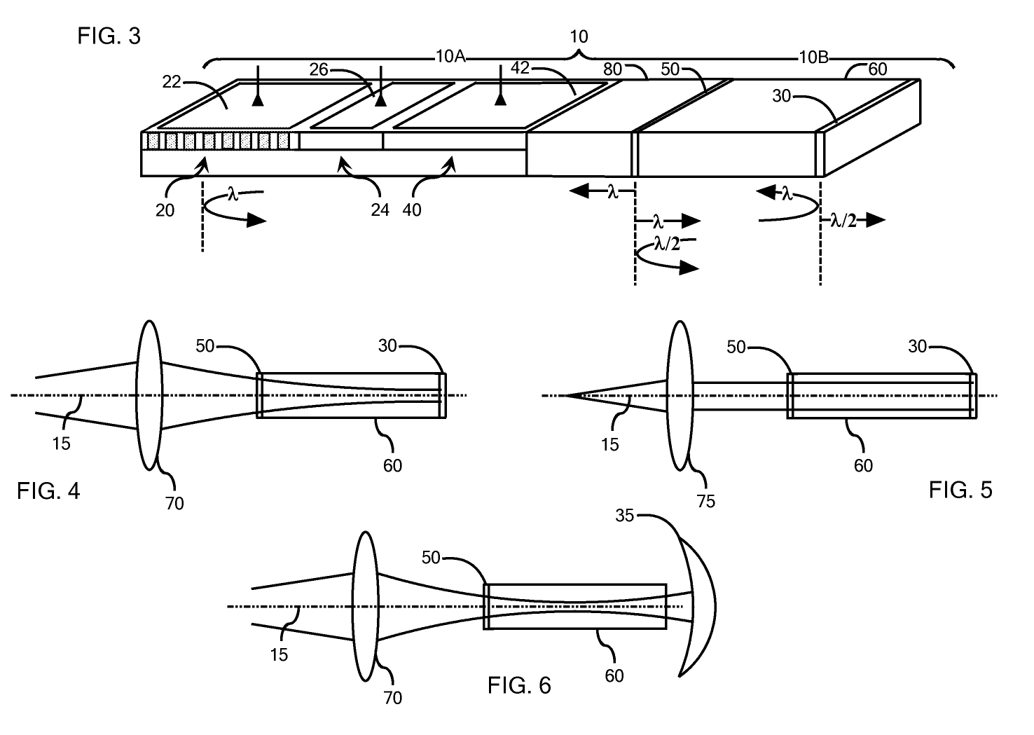

To achieve highly efficient intra-cavity wavelength conversion, it is often helpful to have highly efficient coupling between the SOA 40 and wavelength conversion device 60. FIG. 3 illustrates the use of a two-dimensional beam converter 80 positioned along the optical path 15. The beam converter 80 is configured to expand the mode field diameter of the fundamental laser signal so that to reduce beam divergence of the SOA and expand its mode-field diameter so that it matches the mode-field diameter of the wavelength conversion device 60. The beam converter 80 acts as a bridge between the SOA 40 and the wavelength conversion device 60. Highly efficient coupling is achieved by designing the converter 80 so that it has the same dimensions as the SOA 40 and the wavelength conversion device 60 at both of its ends, respectively. The converter 80 can be a bulk component made of conventional optical material, such as glass, sapphire, and crystals. Alternatively, the converter 80 can also be a waveguide made of semiconductor materials, such as InGaAs, and GaAlAs. Similar to the bulk converter, the waveguide core may be tapered in both fast and slow axes to achieve optimal coupling efficiency. A tapered waveguide can also be achieved by varying dopant concentrations or refractive indexes along the beam propagation axis.

The DBR tuning elements 22 illustrated in FIGS. 1-3 comprise electrodes that are configured for the injection of electrical current into the tunable DBR 20. Alternatively, the DBR tuning elements 22 may comprises heating elements that are configured to control the temperature of the tunable DBR 20. In either case, as is illustrated, the laser source may further comprise a phase control section 24 and a phase tuning element 26 that are configured to cooperate with the tunable DBR 20 to tune the wavelength of the fundamental laser signal λ. The specific structure and function of the DBR and phase control sections may be gleaned from conventional and yet-to-be developed publications related to semiconductor optical amplifiers and DBR lasers.

By using the tunable DBR 20 with the SOA 40, the embodiments proposed herein provide a convenient method to match the wavelength of fundamental light λ to the QPM wavelength of the wavelength conversion device 60. The tuning of the grating for the proposed design can, for example, be achieved by a highly efficient micro heater integrated along the grating section. The bandwidth of the reflective grating is preferably narrower than the bandwidth of the QPM bandwidth, a characteristic that can be enabled by providing a relatively long grating section consisting of many periods.

Although in FIGS. 1 and 3, the output reflector 30 comprises a dichroic mirror coating formed on an output facet of the wavelength conversion device 60, it is contemplated that a variety of optical components may be employed as the output reflector. For example, as is illustrated in FIG. 2, the output reflector may comprise a volume Bragg grating 32 characterized by a suitably configured reflectivity, preferably having a relatively narrow line width, e.g., less than approximately 0.2 nm. When using the volume Bragg grating 32 as the output reflector it will often be preferable to position a collimating lens 34 along the optical path 15 between the volume Bragg grating 32 and the output facet of the wavelength conversion device 60. Further, the laser source may further comprise an anti-reflective coating 65 on the output facet of the wavelength conversion device 60 and the opposing input facet of the volume Bragg grating 32 for substantially non-reflective transmission of the fundamental laser signal λ and the wavelength-converted optical signal λ/2.

Quasi-phase matching is a technique for achieving similar results to those with phase matching of nonlinear interactions, in particular for nonlinear frequency conversion. Instead of a homogeneous nonlinear crystal material, a material with spatially modulated nonlinear properties is used. The idea is essentially to allow for a phase mismatch over some propagation distance, but to reverse (or disrupt) the nonlinear interaction at positions where otherwise the interaction would take place with the wrong direction of conversion. QPM is achieved with periodically poled crystals. The periodically poled nonlinear optical materials are up to 20 times more efficient at second-harmonic generation than crystals of the same material without periodic structure. The material for the crystals is usually a wide band gap inorganic crystal, or in some cases a suitable organic polymer. Some popular materials in current use are KTP, lithium niobate, and lithium tantalate.

Having described the subject matter of the present disclosure in detail and by reference to specific embodiments thereof, it will be apparent that modifications and variations are possible without departing from the scope of the invention defined in the appended claims. More specifically, although some aspects of the present disclosure are identified herein as preferred or particularly advantageous, it is contemplated that the present disclosure is not necessarily limited to these aspects.

It is noted that recitations herein of a component of the present disclosure being “configured” in a particular way, to embody a particular property, or to function in a particular manner, are structural recitations, as opposed to recitations of intended use. More specifically, the references herein to the manner in which a component is “configured” denotes an existing physical condition of the component and, as such, is to be taken as a definite recitation of the structural characteristics of the component.

It is noted that terms like “preferably,” “commonly,” and “typically,” when utilized herein, are not utilized to limit the scope of the claimed invention or to imply that certain features are critical, essential, or even important to the structure or function of the claimed invention. Rather, these terms are merely intended to identify particular aspects of an embodiment of the present disclosure or to emphasize alternative or additional features that may or may not be utilized in a particular embodiment of the present disclosure.

For the purposes of describing and defining the present invention it is noted that the term “approximately” is utilized herein to represent the inherent degree of uncertainty that may be attributed to any quantitative comparison, value, measurement, or other representation. The term “approximately” is also utilized herein to represent the degree by which a quantitative representation may vary from a stated reference without resulting in a change in the basic function of the subject matter at issue.

It is noted that one or more of the following claims utilize the term “wherein” as a transitional phrase. For the purposes of defining the present invention, it is noted that this term is introduced in the claims as an open-ended transitional phrase that is used to introduce a recitation of a series of characteristics of the structure and should be interpreted in like manner as the more commonly used open-ended preamble term “comprising.”

1. An external cavity laser source comprising an external laser cavity, a tunable distributed Bragg reflector (DBR), a DBR tuning element, an output reflector, a semiconductor optical amplifier (SOA), a frequency-selective optical coupler/reflector, and a wavelength conversion device, wherein:
the external laser cavity is defined along an optical path between the tunable DBR and the output reflector;
the SOA is positioned in the external laser cavity along the optical path between the tunable DBR and the frequency-selective optical coupler/reflector;
the wavelength conversion device is characterized by a QPM bandwidth and is positioned in the external laser cavity along the optical path between the frequency-selective optical coupler/reflector and the output reflector;
the tunable DBR, the DBR tuning element, the SOA, and the output reflector are configured to generate a fundamental laser signal characterized by a fundamental bandwidth that is narrower than the QPM bandwidth and can be tuned to a fundamental center wavelength within the QPM bandwidth;
the frequency-selective optical coupler/reflector is configured for substantially non-reflective two-way transmission of optical signals at the fundamental center wavelength and is further configured for substantially complete reflection of wavelength-converted optical signals generated by the wavelength conversion device such that
downstream optical signals at the fundamental center wavelength originating from a DBR side of the external laser cavity are transmitted along the optical path towards the wavelength conversion device and the output reflector and
upstream optical signals at the fundamental center wavelength originating from an output side of the external laser cavity are transmitted along the optical path towards the SOA and the tunable DBR;
the output reflector is configured for substantially non-reflective transmission of wavelength-converted optical signals generated by the wavelength conversion device and for substantially complete reflection of optical signals at the fundamental center wavelength.

2. An external cavity laser source as claimed in claim 1 wherein the frequency-selective optical coupler/reflector comprises a dichroic mirror.

3. An external cavity laser source as claimed in claim 2 wherein the dichroic mirror is formed on an output facet of the SOA, an input facet of the wavelength conversion device, or both.

4. An external cavity laser source as claimed in claim 3 wherein the dichroic mirror comprises a directly-deposited coating.

5. An external cavity laser source as claimed in claim 1 wherein the SOA comprises a gain section configured to provide optical gain at the fundamental center wavelength under electrical current injection.

6. An external cavity laser source as claimed in claim 1 wherein the SOA and the tunable DBR are fabricated on a common substrate.

7. An external cavity laser source as claimed in claim 1 wherein the laser source further comprises one or more coupling lenses positioned along the optical path between the SOA and the wavelength conversion device.

8. An external cavity laser source as claimed in claim 7 wherein the wavelength conversion device comprises a bulk crystal and the coupling lens comprises a focusing lens configured to define a beam waist at an output facet of the bulk crystal.

9. An external cavity laser source as claimed in claim 7 wherein the wavelength conversion device comprises a bulk crystal and the coupling lens comprises a collimating lens configured to collimate the fundamental laser signal to a cross sectional diameter of between approximately 5 μm and approximately 50 μm as it propagates along the optical path through the bulk crystal.

10. An external cavity laser source as claimed in claim 7 wherein the wavelength conversion device comprises a bulk crystal, the coupling lens comprises a focusing lens, and the output reflector comprises a concave reflector, and the focusing lens and the concave reflector cooperate to define a beam waist in an intermediate location along the optical path in the bulk crystal.

11. An external cavity laser source as claimed in claim 1 wherein the laser source further comprises anti-reflective coatings on opposing faces of the SOA and the wavelength conversion device for substantially non-reflective transmission of the fundamental laser signal.

12. An external cavity laser source as claimed in claim 1 wherein the laser source further comprises a two-dimensional beam converter positioned along the optical path, the beam converter configured to expand the mode field diameter of the fundamental laser signal.

13. An external cavity laser source as claimed in claim 1 wherein the DBR tuning element comprises one or more electrodes configured for the injection of electrical current into the tunable DBR.

14. An external cavity laser source as claimed in claim 1 wherein the DBR tuning element comprises one or more heating elements configured to control the temperature of the tunable DBR.

15. An external cavity laser source as claimed in claim 1 wherein the laser source further comprises a phase control section and a phase tuning element configured to cooperate with the tunable DBR to tune the wavelength of the fundamental laser signal.

16. An external cavity laser source as claimed in claim 1 wherein the output reflector comprises a dichroic mirror coating formed on an output facet of the wavelength conversion device.

17. An external cavity laser source as claimed in claim 1 wherein the output reflector comprises a volume Bragg grating characterized by a reflectivity line width of less than approximately 0.2 nm.

18. An external cavity laser source as claimed in claim 1 wherein the output reflector comprises a volume Bragg grating and the laser source further comprises a collimating lens positioned along the optical path between the volume Bragg grating and an output facet of the wavelength conversion device.

19. An external cavity laser source as claimed in claim 1 wherein the output reflector comprises a volume Bragg grating and the laser source further comprises anti-reflective coatings on opposing faces of the wavelength conversion device and the volume Bragg grating for substantially non-reflective transmission of the fundamental laser signal and the wavelength-converted optical signals.

20. An external cavity laser source comprising an external laser cavity, a tunable distributed Bragg reflector (DBR), a DBR tuning element, an output reflector, a semiconductor optical amplifier (SOA), a frequency-selective optical coupler/reflector, and a wavelength conversion device, wherein:
the external laser cavity is defined along an optical path between the tunable DBR and the output reflector;
the SOA comprises a gain section configured to provide optical gain at a fundamental center wavelength under electrical current injection and is positioned in the external laser cavity along the optical path between the tunable DBR and the frequency-selective optical coupler/reflector;
the SOA and the tunable DBR are fabricated on a common substrate;
the DBR tuning element comprises one or more electrodes or heating elements configured for the injection of electrical current into the tunable DBR or to control the temperature of the tunable DBR;
the wavelength conversion device is characterized by a QPM bandwidth and is positioned in the external laser cavity along the optical path between the frequency-selective optical coupler/reflector and the output reflector;
the tunable DBR, the DBR tuning element, the SOA, and the output reflector are configured to generate a fundamental laser signal characterized by a fundamental bandwidth that is narrower than the QPM bandwidth and can be tuned to the fundamental center wavelength within the QPM bandwidth;
the frequency-selective optical coupler/reflector comprises a dichroic mirror formed on an output facet of the SOA, an input facet of the wavelength conversion device, or both, and configured for substantially non-reflective two-way transmission of optical signals at the fundamental center wavelength and for substantially complete reflection of wavelength-converted optical signals generated by the wavelength conversion device such that
optical signals at the fundamental center wavelength originating from an output reflector side of the frequency-selective optical coupler/reflector are transmitted along the optical path towards the SOA and the tunable DBR and
optical signals at the fundamental center wavelength originating from a DBR side of the frequency-selective optical coupler/reflector are transmitted along the optical path towards the wavelength conversion device and the output reflector; and
the output reflector is configured for substantially non-reflective transmission of wavelength-converted optical signals generated by the wavelength conversion device and for substantially complete reflection of optical signals at the fundamental center wavelength.
